(19) United States
(12) Patent Application Publication
(10) Pub. No.: US 2026/0019059 A1
(43) Pub. Date: Jan. 15, 2026

(54) PIEZOELECTRIC RESONATOR WITH BUILT-IN TEMPERATURE SENSOR AND REFERENCE SIGNAL GENERATION DEVICE

(71) Applicant: NIHON DEMPA KOGYO CO., LTD., Tokyo (JP)

(72) Inventor: Wataru SUEMORI, Saitama (JP)

(73) Assignee: NIHON DEMPA KOGYO CO., LTD., Tokyo (JP)

(21) Appl. No.: 19/207,374

(22) Filed: May 14, 2025

(30) Foreign Application Priority Data
Jul. 12, 2024 (JP) 2024-112164

(51) Int. Cl. H03H 9/02; H03H 9/19

(52) U.S. Cl. CPC H03H 9/02448; H03H 9/02259; H03H 9/19

(57) ABSTRACT

A piezoelectric resonator with a built-in temperature sensor is used by being connected to an external electronic device including a temperature compensation circuit. The piezoelectric resonator includes a piezoelectric vibrating piece having a frequency versus temperature characteristic and a temperature sensor. The temperature sensor has its inter-terminal voltage detected as temperature information by the external electronic device. The piezoelectric resonator includes a resistor having one end connected to the temperature sensor and another end connected to a predetermined power source of the connected external electronic device. The resistor has a first resistance value for allowing the inter-terminal voltage to be a planned voltage using a preliminarily determined correction formula, or a second resistance value smaller than the first resistance value or a third resistance value larger than the first resistance value for allowing the inter-terminal voltage to be a correction voltage corresponding to an individual difference of the piezoelectric resonator.

### CROSS-REFERENCE TO RELATED APPLICATIONS

This application is based on and claims priority under 35 U.S.C. § 119 to Japanese Patent Application No. 2024-112164, filed on Jul. 12, 2024, the entire content of which is incorporated herein by reference.

### TECHNICAL FIELD

This disclosure relates to a piezoelectric resonator having a built-in temperature sensor, such as a thermistor, and a reference signal generation device including the same.

### DESCRIPTION OF THE RELATED ART

What is called a crystal unit with a built-in temperature sensor that has an AT-cut quartz-crystal vibrating piece and a temperature sensor (typically, a thermistor) built into one container has been heavily used in recent years. Typical examples thereof include a single-chamber-structure one and an H-shaped-structure one.

The former has a quartz-crystal vibrating piece and a temperature sensor mounted and airtightly sealed within one chamber (for example, paragraph 75, FIG. 7, and the like in Japanese Unexamined Patent Application Publication No. 2023-70552). The latter has a first chamber in which a quartz-crystal vibrating piece is mounted and a second chamber in which a temperature sensor is mounted, the first chamber and the second chamber are stacked back to back, and the first chamber is airtightly sealed (for example, Abstract, FIG. 1, and the like in Japanese Unexamined Patent Application Publication No. 2022-140662).

Both the single-chamber-structure one and the H-shaped-structure one are used by being connected to a chipset (external electronic device) designed on the assumption of using these crystal units. On the basis of temperature information detected by the temperature sensor, an oscillation frequency of the quartz-crystal vibrating piece is corrected on a chipset side, and therefore, a target frequency is obtainable with higher accuracy.

The above-described correction is performed using a preliminarily determined correction formula built into the external electronic device. In order to inexpensively manufacture this external electronic device, the preliminarily determined correction formula is also preferred to be simple. Therefore, a correction formula for an approximation formula approximating a representative frequency versus temperature characteristic among respective frequency versus temperature characteristics of many crystal units used in combination with the external electronic device is used as the correction formula (see FIG. 3A and FIG. 3B described below).

However, since the correction formula is determined on the basis of the representative frequency versus temperature characteristic of the crystal units, a problem arises in that a crystal unit with a frequency versus temperature characteristic deviated from the representative frequency versus temperature characteristic due to a production tolerance and the like has a deviation from an ideal correction (see FIG. 4A and FIG. 4B described below).

When the crystal unit with the built-in temperature sensor is used as a reference signal source with higher accuracy, for example, when used as a reference signal source of, for example, Bluetooth (registered trademark) and WLAN (Wireless LAN), a variation in frequency with respect to a variation in ambient temperature is preferred to be as small as possible in order to satisfy frequency deviations specified by law and communication standards. There is an increasing desire on the assumption of the use under a high temperature at which the variation in frequency is increased. Accordingly, it is increasingly desired to provide higher accuracy while achieving inexpensiveness, and therefore, it is preferred that the above-described problems be solved.

A need thus exists for a piezoelectric resonator with a built-in temperature sensor and a reference signal generation device which are not susceptible to the drawback mentioned above.

### SUMMARY

According to a first aspect of this disclosure, there is provided a piezoelectric resonator with a built-in temperature sensor used by being connected to an external electronic device including a temperature compensation circuit. The temperature compensation circuit compensates an oscillation frequency of a piezoelectric vibrating piece in accordance with temperature information detected by a temperature sensor and a preliminarily determined correction formula. The piezoelectric resonator includes the piezoelectric vibrating piece having a frequency versus temperature characteristic and the temperature sensor. The temperature sensor has an inter-terminal voltage thereof detected as the temperature information by the external electronic device. The piezoelectric resonator includes a resistor having one end connected to the temperature sensor and another end connected to a predetermined power source of the external electronic device. The resistor has a first resistance value for allowing the inter-terminal voltage to be a planned voltage using the preliminarily determined correction formula, or a second resistance value smaller than the first resistance value or a third resistance value larger than the first resistance value for allowing the inter-terminal voltage to be a correction voltage corresponding to an individual difference of the piezoelectric resonator.

The first resistance value is, in other words, a resistance value at which a desired temperature compensation result can be obtained by the correction formula stored in advance in the external electronic device.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a drawing for describing a piezoelectric resonator 10 with a built-in temperature sensor and a reference signal generation device 21 according to an embodiment;

FIG. 2 is a drawing for deeply understanding the disclosure and a drawing for describing a conventional piezoelectric resonator 30 with a built-in temperature sensor;

FIG. 3A and FIG. 3B are drawings for describing an action and effect of the piezoelectric resonator 10 according to the embodiment; and

FIG. 4A and FIG. 4B are drawings continuous with FIG. 3A and FIG. 3B for describing the action and effect of the piezoelectric resonator 10 according to the embodiment.

### DETAILED DESCRIPTION

The following describes embodiments of a piezoelectric resonator with a built-in temperature sensor of this disclosure with reference to the attached drawings. Each drawing used in the description merely gives a schematic illustration for understanding this disclosure. In each drawing used in the description, identical reference numerals designate similar elements, and therefore, descriptions thereof may be omitted here. Circuit configurations, numerical value examples, and similar factors described in the following descriptions are merely preferred examples within the scope of this disclosure. Therefore, this disclosure is not limited only to the following embodiments.

### 1. Configuration of Piezoelectric Resonator

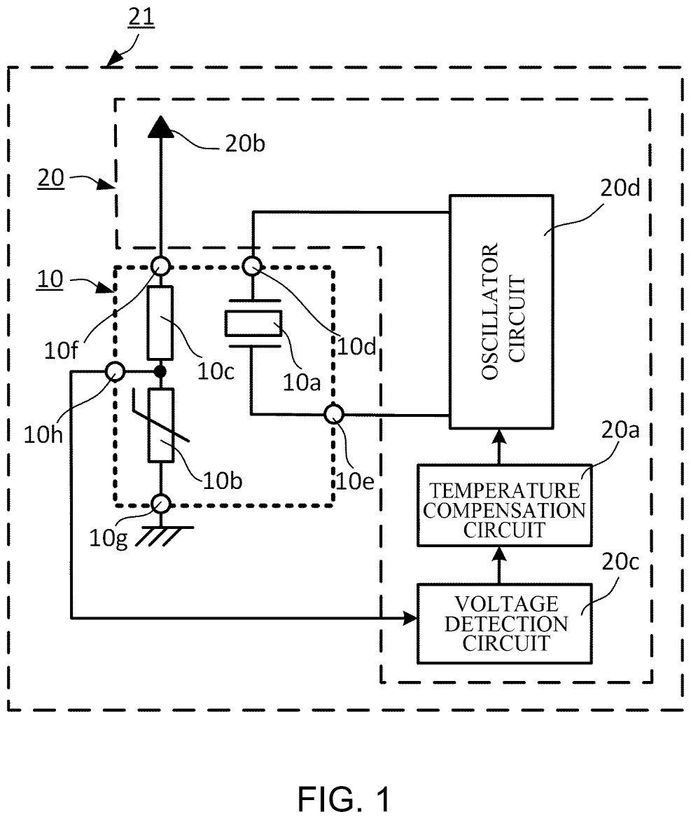

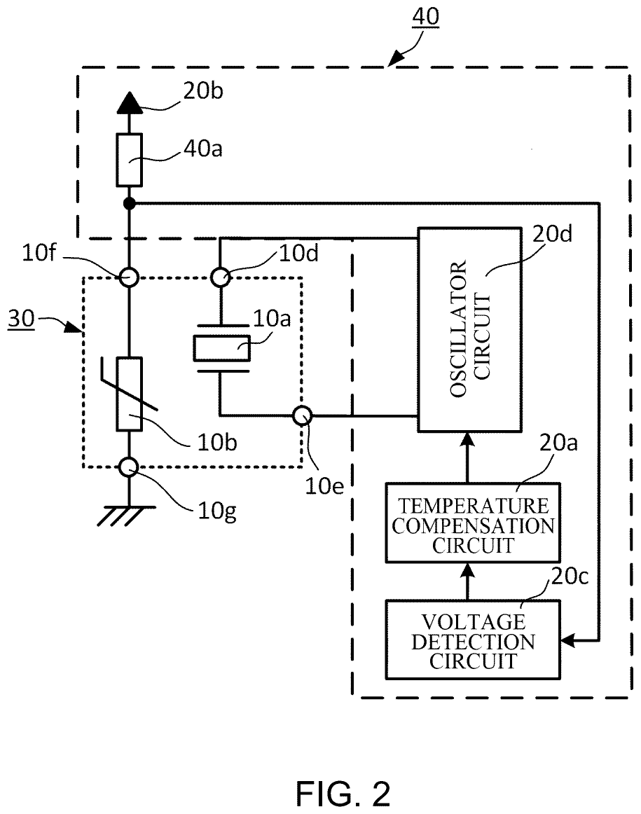

FIG. 1 is a drawing for describing a piezoelectric resonator 10 according to an embodiment. It is a block diagram illustrating together with an external electronic device 20 to which this piezoelectric resonator 10 is connected. FIG. 2 is a drawing for deeply understanding the disclosure, and is a block diagram illustrating a conventional piezoelectric resonator 30 together with an external electronic device 40 to which this piezoelectric resonator 30 is connected.

The piezoelectric resonator 10 according to the embodiment is a piezoelectric resonator with a built-in temperature sensor including a piezoelectric vibrating piece 10a with a frequency versus temperature characteristic and a temperature sensor 10b, and is a piezoelectric resonator used by being connected to the external electronic device 20 having a temperature compensation circuit 20a that compensates an oscillation frequency of the piezoelectric vibrating piece 10a in accordance with temperature information detected by the temperature sensor 10b and a preliminarily determined correction formula.

The piezoelectric vibrating piece 10a included in the piezoelectric resonator 10 is an AT-cut quartz-crystal vibrating piece in this embodiment.

The temperature sensor 10b has its inter-terminal voltage detected as the temperature information by the external electronic device 20. The temperature sensor 10b can be any given preferred one, and in this embodiment, the temperature sensor 10b is constituted of an NTC (negative temperature coefficient) thermistor.

The piezoelectric resonator 10 includes a resistor 10c having one end connected to the temperature sensor 10b and the other end connected to a predetermined power source 20b of the external electronic device 20, which is a feature of the present disclosure. While the detail will be described in the section of Action and Effect described later, this resistor 10c is a resistor having a first resistance value that allows the inter-terminal voltage of the temperature sensor 10b to be a planned voltage using the preliminarily determined correction formula or a resistor having a second resistance value smaller than the first resistance value or having a third resistance value larger than the first resistance value that allows the inter-terminal voltage to be a correction voltage corresponding to an individual difference of the piezoelectric resonator. The resistor 10c and the temperature sensor 10b configure a series circuit. The temperature sensor 10b has a terminal on the opposite side of a terminal connected to the resistor 10c that is connected to a line with a predetermined electric potential, such as a ground.

The piezoelectric vibrating piece 10a, the temperature sensor 10b, and the resistor 10c are built into any given preferred container, for example, an airtight container made of ceramic. Furthermore, the piezoelectric resonator 10 includes a first terminal 10d and a second terminal 10e for the piezoelectric vibrating piece 10a, a third terminal 10f and a fourth terminal 10g for the temperature sensor 10b and the resistor 10c, and a fifth terminal 10h connected to a connection point between the temperature sensor and the resistor, as external terminals for connecting to the external electronic device 20. These terminals 10d to 10h are, for example, disposed on, for example, an outer bottom surface of the above-described ceramic container. Note that, while the illustration is omitted, the present disclosure is surely applicable to both a single-chamber piezoelectric resonator with a built-in temperature sensor and an H-shaped piezoelectric resonator with a built-in temperature sensor.

Note that the external electronic device 20 includes a voltage detection circuit 20c that detects the inter-terminal voltage of the temperature sensor 10b and an oscillator circuit 20d for the piezoelectric vibrating piece 10a. These temperature compensation circuit 20a, the predetermined power source 20b, the voltage detection circuit 20c, and the oscillator circuit 20d can be constituted of known ones. In the case of this embodiment, the piezoelectric resonator 10 and the external electronic device 20 can constitute a reference signal generation device 21 corresponding to a second aspect of this disclosure.

The external electronic device 20 may be any kind that can use the piezoelectric resonator 10, and is, for example, a chipset provided by a chipset supplier, and furthermore, a Bluetooth (registered trademark) device, a WLAN device, or the like that uses the chipset.

As can be seen by referring to the block diagram of the conventional piezoelectric resonator 30 and external electronic device 40 illustrated in FIG. 2, the conventional one has a configuration in which a fixed resistor 40a is included on a side of the external electronic device and the piezoelectric resonator 30 includes the piezoelectric vibrating piece 10a and the temperature sensor 10b, whereas the piezoelectric resonator 10 of the present disclosure has a configuration in which a predetermined resistor having the first resistance value, the second resistance value, or the third resistance value is provided on a side of the piezoelectric resonator 10 and no resistor is provided on a side of the external electronic device 20. However, a resistor is surely allowed to be provided on the external electronic device 20 side for the purpose of circuit protection or the like. In such a case, a divided voltage according to the present disclosure is determined taking this resistor into consideration.

### 2. Action and Effect of Present Disclosure

Next, in order to deeply understand the present disclosure, actions and effects generated by the configuration of the present disclosure will be described with specific examples.

A temperature characteristic of a resistance value Rth of the NTC thermistor as the temperature sensor 10b can, for example, be approximated using the formula below. Note that in the following formula, To is a reference temperature (for example, 25° C.), T is an ambient temperature, Ro is a resistance value at the reference temperature, and B is a constant.

$$Rth = Ro / {e}^{B ( 1 / T - 1 / T o )}$$

Accordingly, a voltage Vth at a midpoint in the series circuit of the resistor 10c and the temperature sensor 10b illustrated in FIG. 1 is obtained as a value of a voltage Vbias of the power source 20b divided by the resistance value Rth of the thermistor and a resistance value r of the resistor 10c, thus being a voltage shown in the formula below.

$$Vth = Rth \cdot Vbias / ( r + Rth )$$

Accordingly, the temperature information obtained from a voltage detected by the temperature sensor 10b is the information shown in the formula below. Note that in the following formula, T is an ambient temperature (temperature information), and To is any reference temperature (for example, 25° C.).

$$T = \frac{{T}_{0} \cdot B}{{T}_{0} \cdot ln \frac{{rV}_{th}}{{R}_{0} \cdot ( {V}_{bias} - {V}_{th} )} + B}$$

On the other hand, the frequency versus temperature characteristic of the AT-cut quartz-crystal vibrating piece 10a can be approximated using a high order approximation formula, briefly, for example, the cubic approximation formula below. Note that in the following formula, T is an ambient temperature, To is any reference temperature (for example, 25° C.), F is an oscillation frequency of the crystal unit at the reference temperature To, dF is a difference between an oscillation frequency Fn of the quartz-crystal vibrating piece at a certain temperature and the oscillation frequency F of the quartz-crystal vibrating piece at the reference temperature (F−Fn), and dF/F is a frequency deviation caused by a change in the ambient temperature. In addition, a, b, c, and d are coefficients.

$$dF / F = a {( T - T o )}^{3} + b {( T - T o )}^{2} + c ( T - T o ) + d$$

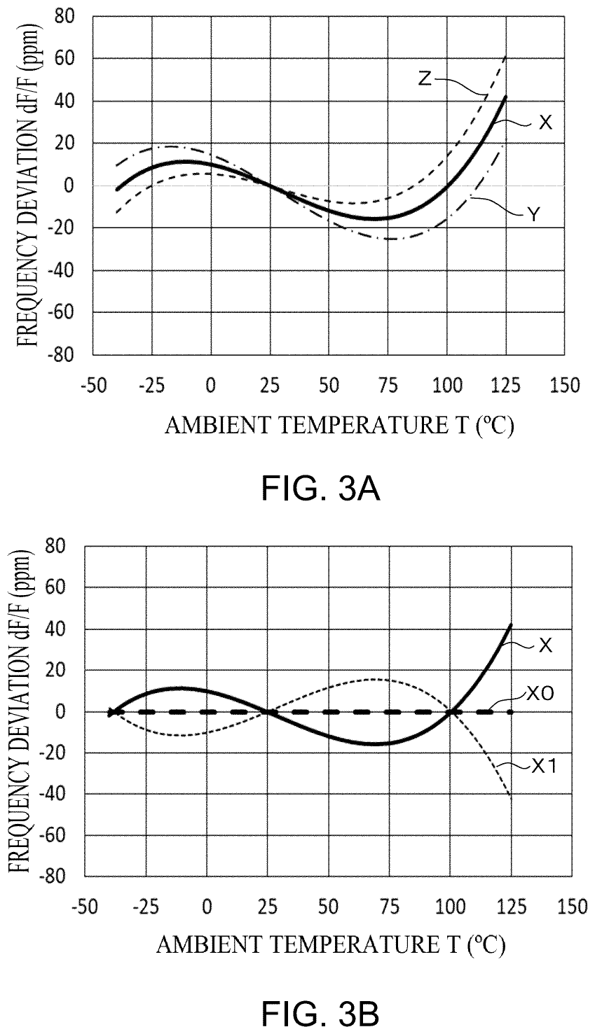

Here, the frequency versus temperature characteristic of the crystal unit is different for each crystal unit. As examples of many different frequency versus temperature characteristics, FIG. 3A shows three temperature characteristics, a first frequency versus temperature characteristic X, a second frequency versus temperature characteristic Y, and a third frequency versus temperature characteristic Z, in order to make the descriptions and the drawing easy. Note that the horizontal axis indicates a temperature, and the vertical axis indicates a frequency deviation in FIG. 3A and FIG. 3B. A constant C is 0 for simplifying the descriptions. This is for matching the frequencies at 25° C. of the three kinds of exemplified frequency versus temperature characteristics X, Y, Z.

Accordingly, in the case of this embodiment, these three temperature characteristics are assumed as some frequency versus temperature characteristics generated due to a production tolerance and the like, and the first frequency versus temperature characteristic X is assumed as a representative frequency versus temperature characteristic.

| | Y | X | Z |
|---|---|---|---|
| a | 0.000106 | 0.000105 | 0.000105 |
| b | −0.001478 | −0.001287 | −0.001069 |
| d | −0.690955 | −0.500436 | −0.322446 |
| c | 0 | 0 | 0 |

In the case of the above-described assumptions, a correction formula preliminarily stored in the temperature compensation circuit 20a included in the external electronic device 20 to which the piezoelectric resonator 10 of the embodiment is connected is a correction formula based on the first frequency versus temperature characteristic X.

For example, when it is assumed that the voltage Vbias of the power source 20b=3 V, the constant B of the temperature sensor 10b =4250 K, and the resistance value Ro at the reference temperature 25° C. of the temperature sensor =100 kΩ, the first resistance value of the resistor 10c according to the present disclosure, that is, the first resistance value with which a desired temperature compensation result is obtainable using the correction formula preliminarily stored in the external electronic device is typically 100 kΩ. This is because the first resistance value is typically set so as to allow the voltage of the terminal 10h to be half a value of Vbias.

In the case of the piezoelectric resonator 10 of the present disclosure, since the resistor 10c having the first resistance value, the second resistance value, or the third resistance value is disposed, the temperature compensation as follows is possible.

### First Temperature Compensation Example

As a first example, the case where a crystal unit having the representative frequency versus temperature characteristic (the first frequency versus temperature characteristic X) is connected to the external electronic device 20 is considered. In this case, the resistor 10c provided in the crystal unit 10 is a resistor having the first resistance value that allows the inter-terminal voltage of the temperature sensor 10b (the voltage of the terminal 10h in FIG. 1) to be a planned voltage using the preliminarily determined correction formula, that is, a resistor having a resistance value of 100 kΩ. Accordingly, in the case of this first example, as illustrated in FIG. 3B, the frequency versus temperature characteristic X before correction is successfully corrected using a correction formula X1, and therefore, a frequency versus temperature characteristic X0 after correction is flat.

### Second Temperature Compensation Example

As a second example, the case where a crystal unit having the second frequency versus temperature characteristic Y illustrated in FIG. 3A is connected to the external electronic device 20 is considered. That is, the case where the crystal unit having the temperature characteristic Y in a state of being rotated clockwise with respect to the first frequency versus temperature characteristic X is connected is considered. In this case, the resistor 10c is a resistor having the second resistance value smaller than the first resistance value, for example, a resistance value of 90 kΩ in order to make the inter-terminal voltage of the temperature sensor 10b (the voltage of the terminal 10h in FIG. 1) a correction voltage corresponding to the individual difference of the piezoelectric resonator.

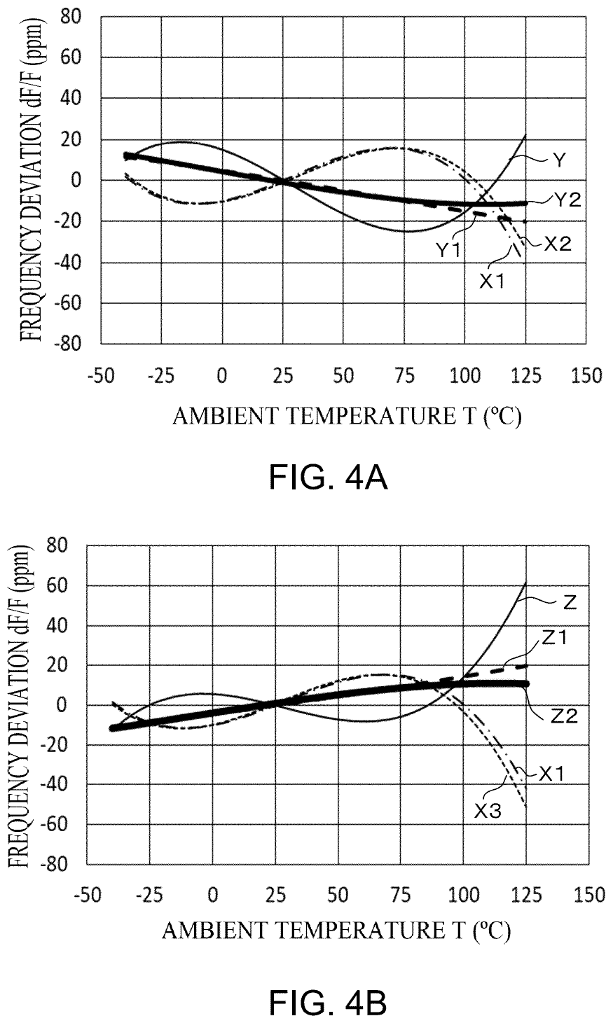

The temperature compensation state in the case of this second example is illustrated in FIG. 4A. Note that FIG. 4A illustrates correction states in the case where the resistor 10c is a resistor of 100 kΩ and in the case where the resistor 10c is a resistor of 90 kΩ together.

As illustrated in FIG. 4A, the correction result when the second frequency versus temperature characteristic Y is corrected using the correction formula X1 based on the resistor (100 kΩ) corresponding to the representative frequency versus temperature characteristic is Y1. In contrast to this, the correction result when the second frequency versus temperature characteristic Y is corrected using a correction formula X2 based on the resistor having the second resistance value (in this case, 90 kΩ) is Y2. It is seen that the correction using the resistor according to the present disclosure having the second resistance value can improve the frequency versus temperature characteristic compared with the correction using the resistor having the first resistance value, and especially, the frequency deviation on the high temperature side can be reduced by approximately 10 ppm.

### Third Temperature Compensation Example

As a third example, the case where a crystal unit having the third frequency versus temperature characteristic Z illustrated in FIG. 3A is connected to the external electronic device 20 is considered. That is, the case where the crystal unit having the temperature characteristic Z in a state of being rotated counterclockwise with respect to the first frequency versus temperature characteristic X is connected is considered. In this case, the resistor 10c is a resistor having the third resistance value larger than the first resistance value, for example, a resistance value of 110 kΩ in order to make the inter-terminal voltage of the temperature sensor 10b (the voltage of the terminal 10h in FIG. 1) a correction voltage corresponding to the individual difference of the piezoelectric resonator.

The temperature compensation state in the case of this third example is illustrated in FIG. 4B. Note that FIG. 4B illustrates correction states in the case where the resistor 10c is a resistor of 100 kΩ and in the case where the resistor 10c is a resistor of 110 kΩ together.

As illustrated in FIG. 4B, the correction result when the third frequency versus temperature characteristic Z is corrected using the correction formula X1 based on the resistor (100 kΩ) corresponding to the representative frequency versus temperature characteristic is Z1. In contrast to this, the correction result when the third frequency versus temperature characteristic Z is corrected using a correction formula X3 based on the resistor having the third resistance value (in this case, 110 kΩ) is Z2. It is seen that the correction using the resistor according to the present disclosure having the third resistance value can improve the frequency versus temperature characteristic compared with the correction using the resistor having the first resistance value, and especially, the frequency deviation on the high temperature side can be reduced by approximately 10 ppm.

As described above, the piezoelectric resonator of the present disclosure includes the resistors correcting the inter-terminal voltage of the temperature sensor to an appropriate value for each piezoelectric resonator, and therefore, it is seen that the frequency versus temperature characteristic after correction can be improved compared with the case without using the resistors. Moreover, only adding an appropriate resistor ensures improving temperature compensation accuracy.

Note that the present disclosure is surely applicable to any of the single-chamber piezoelectric resonator with the built-in temperature sensor and the H-shaped piezoelectric resonator with the built-in temperature sensor.

Here, the second resistance value and the third resistance value are resistance values for allowing correction of a frequency versus temperature characteristic of a crystal unit having a frequency versus temperature characteristic deviated from a representative frequency versus temperature characteristic due to a production tolerance and the like into a direction of improvement compared with a case of the first resistance value, and are resistance values determined corresponding to the frequency versus temperature characteristic. The second resistance value and the third resistance value may be determined for each crystal unit or may be determined by the group formed of a plurality of the crystal units having frequency characteristics within any preferred range.

When this disclosure is executed, the piezoelectric vibrating piece may be any kind having a frequency versus temperature characteristic, and, for example, can be selected from a crystal unit, a piezoelectric ceramic resonator, crystal units constituted of other piezoelectric materials, and the like. However, the piezoelectric vibrating piece is preferably an AT-cut quartz-crystal vibrating piece. This is because the AT-cut quartz-crystal vibrating piece is and will be heavily used as an element for a reference signal source now and in the future, and therefore, the application of the present disclosure allows achieving a more effective reference signal source.

When this disclosure is executed, the piezoelectric resonator preferably includes a first terminal and a second terminal for the piezoelectric vibrating piece, a third terminal and a fourth terminal for the temperature sensor and the resistor, and a fifth terminal connected to a connection point between the temperature sensor and the resistor, as external terminals for connecting to the external electronic device. This configuration allows the effective use of the piezoelectric resonator of the present disclosure.

According to a second aspect of this disclosure, there is provided a reference signal generation device. The reference signal generation device includes the above-described piezoelectric resonator with the built-in temperature sensor and an external electronic device including a temperature compensation circuit that compensates an oscillation frequency of the piezoelectric vibrating piece in accordance with the temperature information detected by the temperature sensor and the preliminarily determined correction formula.

The piezoelectric resonator with the built-in temperature sensor of the first aspect of this disclosure further includes the resistor having the first resistance value, the second resistance value, or the third resistance value for setting (correcting) the inter-terminal voltage of the temperature sensor in contrast to the conventional one. Accordingly, the external electronic device (chipset) to which the piezoelectric resonator of this disclosure is connected inputs the voltage corrected by the resistor as the temperature information of the temperature sensor, and performs the temperature compensation. That is, when the resistance value of the resistor is the first resistance value, the chipset performs the compensation using temperature information that fits the preliminarily determined correction formula. When the resistance value of the resistor is the second resistance value or the third resistance value, the chipset purposely uses temperature information deviated due to the second resistance value or the third resistance value from the temperature information that fits the preliminarily determined correction formula, and performs the compensation using the preliminarily determined correction formula. Accordingly, even in the case of the crystal unit having the frequency versus temperature characteristic deviated from the representative frequency versus temperature characteristic due to a production tolerance and the like, the action of the resistor with the second resistance value or the third resistance value enables a satisfactory temperature compensation compared with the case without this resistor.

With the reference signal generation device according to the second aspect of this disclosure, compared with the conventional one, a highly accurate reference signal can be generated in combination with the piezoelectric resonator according to the first aspect.

In view of this, the piezoelectric resonator with the built-in temperature sensor and the reference signal generation device having novel structures effective in improving the frequency versus temperature characteristic of the piezoelectric resonator compared with the conventional one are providable.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric resonator with a built-in temperature sensor used by being connected to an external electronic device including a temperature compensation circuit, the temperature compensation circuit compensating an oscillation frequency of a piezoelectric vibrating piece in accordance with temperature information detected by a temperature sensor and a preliminarily determined correction formula, the piezoelectric resonator comprising:
the piezoelectric vibrating piece having a frequency versus temperature characteristic; and
the temperature sensor, wherein
the temperature sensor has an inter-terminal voltage thereof detected as the temperature information by the connected external electronic device, and
the piezoelectric resonator comprises a resistor having one end connected to the temperature sensor and another end connected to a predetermined power source of the connected external electronic device, and the resistor has a first resistance value for allowing the inter-terminal voltage to be a planned voltage using the preliminarily determined correction formula, or a second resistance value smaller than the first resistance value or a third resistance value larger than the first resistance value for allowing the inter-terminal voltage to be a correction voltage corresponding to an individual difference of the piezoelectric resonator.

2. The piezoelectric resonator with the built-in temperature sensor according to claim 1, wherein
the second resistance value and the third resistance value are resistance values for allowing correction of a frequency versus temperature characteristic of a crystal unit having a frequency versus temperature characteristic deviated from a representative frequency versus temperature characteristic into a direction of improvement compared with a case of the first resistance value.

3. The piezoelectric resonator with the built-in temperature sensor according to claim 1, wherein
the piezoelectric resonator includes a first terminal and a second terminal for the piezoelectric vibrating piece, a third terminal and a fourth terminal for the temperature sensor and the resistor, and a fifth terminal connected to a connection point between the temperature sensor and the resistor, as external terminals for connecting to the connected external electronic device.

4. The piezoelectric resonator with the built-in temperature sensor according to claim 1, wherein
the piezoelectric vibrating piece is an AT-cut quartz-crystal vibrating piece.

5. A reference signal generation device comprising:
the piezoelectric resonator with the built-in temperature sensor according to claim 1; and
an external electronic device including a temperature compensation circuit that compensates an oscillation frequency of the piezoelectric vibrating piece in accordance with the temperature information detected by the temperature sensor and the preliminarily determined correction formula.

6. The reference signal generation device according to claim 5, wherein
the piezoelectric vibrating piece is an AT-cut quartz-crystal vibrating piece.
